(19) United States
(12) Patent Application Publication
(10) Pub. No.: US 2023/0386875 A1
(43) Pub. Date: Nov. 30, 2023

(54) UNDER BOAT SUPPORT WITH ELECTROSTATIC DISCHARGE STRUCTURE

(71) Applicant: Taiwan Semiconductor Manufacturing Co., Ltd., Hsinchu (TW)

(72) Inventors: Ying-Hao WANG, Tainan City (TW); Chien-Lung CHEN, Zhubei City (TW); Wei-Hao CHEN, Hsinchu City (TW); Chien-Chi TZENG, Hsinchu City (TW); Hu-Wei LIN, Hsinchu City (TW)

(21) Appl. No.: 18/162,538

(22) Filed: Jan. 31, 2023

Related U.S. Application Data
(60) Provisional application No. 63/405,202, filed on Sep. 9, 2022.
(60) Provisional application No. 63/346,284, filed on May 26, 2022.

(51) Int. Cl. H01L 21/673

(52) U.S. Cl. CPC H01L 21/6733; H01L 21/67336; H01L 21/67396

(57) ABSTRACT

An under boat support (UBS) includes an electrostatic discharge (ESD) safe ceramic body and a conductive body. The ESD safe ceramic body is coupled to a surface of the conductive body by an adhesive, which may be resistant to high temperatures. A plurality of springs are present within the adhesive and extend from the surface of the conductive body to a surface of the ESD safe ceramic body. For example, first ends of the plurality of springs are electrically coupled to the surface of the conductive body, and second ends of the plurality of springs, which are opposite to corresponding ones of the first ends of the plurality of springs, are electrically coupled to the surface of the ESD safe ceramic body. The plurality of springs form electrical pathways such that the ESD safe ceramic body is electrically coupled to the conductive body.

### PRIORITY CLAIM AND CROSS-REFERENCE

This application claims benefit of U.S. Provisional Patent Application No. 63/346,284 filed May 26, 2022, and claims benefit of U.S. Provisional Patent Application No. 63/405,202 filed Sep. 9, 2022, which are both incorporated by reference herein in their entirety.

### BACKGROUND

Generally, in the manufacture of semiconductor devices, semiconductor packages, or integrated circuits within a semiconductor manufacturing plant (FAB), several workpieces or components (e.g., wafers, pattern lenses, dummy wafers, etc.) are patterned and processed utilizing various techniques (e.g., etching, patterning, EUV lithography, etc.) to refine and process the workpieces, as well as utilizing various techniques (e.g., die attach, lid attach, pick and place, wire-bonding, etc.) to form semiconductor packages or integrated circuit packages. These processing steps performed by various workpiece processing tools within the FAB result in the formation of many semiconductor devices, packages, or integrated circuits.

During the manufacture of semiconductor devices, semiconductor packages, or integrated circuits within the FAB, the workpieces and various components of the semiconductor devices, semiconductor packages, and integrated circuits are supported by support structures or boats while being processed by the various workpiece processing tools or semiconductor device, package, or integrated circuit manufacturing tools. For example, at least some components of a partially constructed semiconductor device, package, or integrated circuit may be supported by an under boat support.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of an example of an under boat support.

FIG. 1B is a top plan view of the example of the under boat support as shown in FIG. 1A.

FIG. 1C is a side view of the example of the under boat support as shown in FIGS. 1A and 1B.

FIG. 1D is a cross-sectional view of the example of the under boat support as shown in FIGS. 1A-1C taken along line 1D-1D as shown in FIG. 1B.

FIG. 2A is an exploded, perspective view of an under boat support, in accordance with some embodiments.

FIG. 2B is a cross-sectional view of the under boat support as shown in FIG. 2A, in accordance with some embodiments, taken along line 2B-2B as shown in FIG. 2A.

FIG. 3 is a cross-sectional view of an example of a completed semiconductor package.

FIG. 4 is a top plan view of an example of a carrier on which a partially processed semiconductor package is present.

FIG. 5 is a flowchart of a method of manufacturing one or more semiconductor devices, semiconductor packages, or integrated circuits, in accordance with some embodiments.

FIGS. 6A-6C are side views of a method of manufacturing one or more semiconductor devices, semiconductor packages, or integrated circuits, in accordance with some embodiments.

FIG. 7 is a flowchart of a method of manufacturing the under boat support as shown in FIGS. 2A and 2B, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Generally, semiconductor devices, semiconductor packages, or integrated circuits are manufactured within a semiconductor manufacturing or fabrication plant (FAB). These semiconductor devices, semiconductor packages, or integrated circuits may be manufactured by refining and processing workpieces such that workpieces eventually become semiconductor devices, semiconductor packages, or integrated circuits. Multiple workpiece processing tools (e.g., etching tools, patterning tools, layer formation tools, sputtering tools, deposition tools, etc.) and device or package manufacturing tools (e.g., pick and place tool, die attach tool, wire bond formation tool, etc.) are utilized within the FAB to refine and process the workpieces and form various structures to form any number of semiconductor devices, semiconductor packages, or integrated circuits. For example, workpieces or partially constructed semiconductor packages or devices may be positioned on a carrier to be transported between various manufacturing tools within the FAB. During these various steps in the manufacturing process utilizing the manufacturing tools, the workpieces or components of the partially constructed semiconductor packages or devices may be exposed electrostatic discharge (ESD) that may damage sensitive or delicate components while processing the workpiece or manufacturing the semiconductor packages, semiconductor devices, or integrated circuits. This damage to these sensitive or delicate components may result in semiconductor devices, semiconductor packages, or integrated circuits being manufactured outside of selected tolerances. This out of tolerance semiconductor devices, semiconductor packages, or integrated circuits generally will not be sold to customers, and, therefore, will become waste and a lost expense.

In view of the above discussion, at least some of the present disclosure is directed to devices, systems, and methods to prevent or reduce the likelihood of electrostatic discharge damaging sensitive or delicate components to become components of a manufactured and completed semiconductor device, semiconductor package, or integrated circuits. For example, an under boat support (UBS) in accordance with some embodiments of the present disclosure includes a conductive body including a first surface, a second surface opposite to the first surface, and plurality of sidewalls that extend from the first surface to the second surface. The plurality of sidewalls of the conductive body are covered by a coating layer, and an adhesive is on the first surface of the conductive body. The adhesive couples an electrostatic discharge (ESD) safe ceramic body to the first surface of the conductive body. A plurality of springs are present within the adhesive and extend from the first surface of the conductive body to the ESD safe ceramic body. The springs are in electrical communication with the ESD safe ceramic body and the conductive body such that an electrical pathway exists between the ESD safe ceramic body and the conductive body.

In at least one embodiment of a method of the present disclosure, a semiconductor package or a die assembly (e.g., a partially formed or manufactured semiconductor package that is still being processed to form a completed semiconductor package) is temporarily coupled to a substrate carrier. The semiconductor package or die assembly may include a base substrate (e.g., a printed circuit board (PCB)), a die on the base substrate and coupled to the base substrate, a lid coupled to the base substrate covering the die, and a thermal interface material (TIM) on the die and between the lid and the die. The TIM extends from the die to an internal surface of the lid such that a thermal dissipation pathway exists between the lid and the die such that thermal energy from the die may be dissipated through the lid. The substrate carrier on which the semiconductor package is present is positioned within a processing tool within a FAB. In at least one instance, the processing tool is a clamp processing tool that is utilized to apply pressure to the die assembly to uniformly distribute the TIM on the die such that the TIM will have a greater contact area such that heat output from the die will more readily be dissipated through the TIM. For example, the clamp processing tool may include a clamp structure with an embodiment of one of the UBSs of the present disclosure and a weighted portion. The ESD safe ceramic body of the UBS is brought into contact with the base substrate and the weighted portion is brought into contact with the lid of the semiconductor package or die assembly. In other words, the semiconductor package or die assembly is clamped onto by the UBS and the weighted portion of the clamp structure resulting in applying a pressure to the semiconductor package and the die assembly. This clamping onto the semiconductor package or die assembly results in the TIM being uniformly distributed onto the die such that the contact area between the TIM and the die is increased in size such that the TIM will more readily dissipate heat output by the die when the completed semiconductor package is utilized, for example, within an electronic device (e.g., smartphone, tablet, computer, calculator, or some other similar or like type of electronically powered device). The weighted portion includes a high temperature resistant plastic portion that contacts the lid of the semiconductor package or die assembly when clamping down onto the semiconductor package or die assembly to uniformly distribute the TIM on the die. As the ESD ceramic body of the UBS is present and contacts the semiconductor package or die assembly to uniformly distribute the TIM on the die, electrostatic discharge while clamping the semiconductor die or die assembly in the clamp structure is reduced or is prevented. This reduction or prevention of electrostatic discharge during this clamping process reduces the likelihood that sensitive electronic components (e.g., the die, electrical connections such as wire bonds, etc.) within the semiconductor package or die assembly are exposed to an electrostatic discharge reducing or preventing the sensitive electronic components being damaged by the electrostatic discharge. This reduction or prevention of electrostatic discharge during this clamping process increases a yield of usable or within tolerance completed and manufactured semiconductor packages or devices that may be sold to customers.

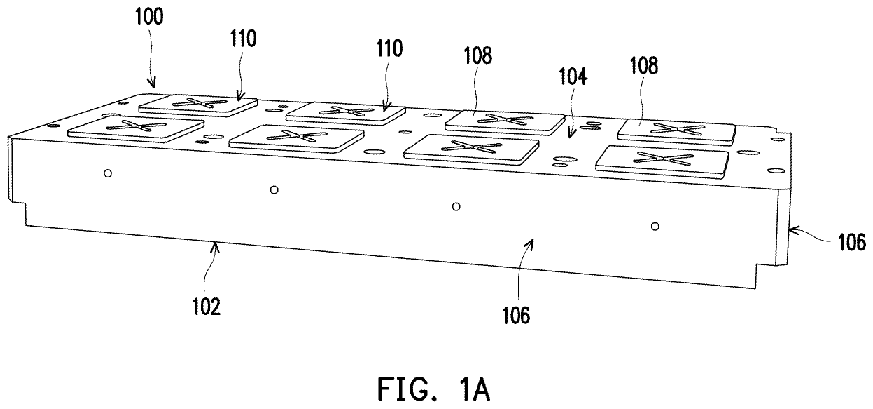

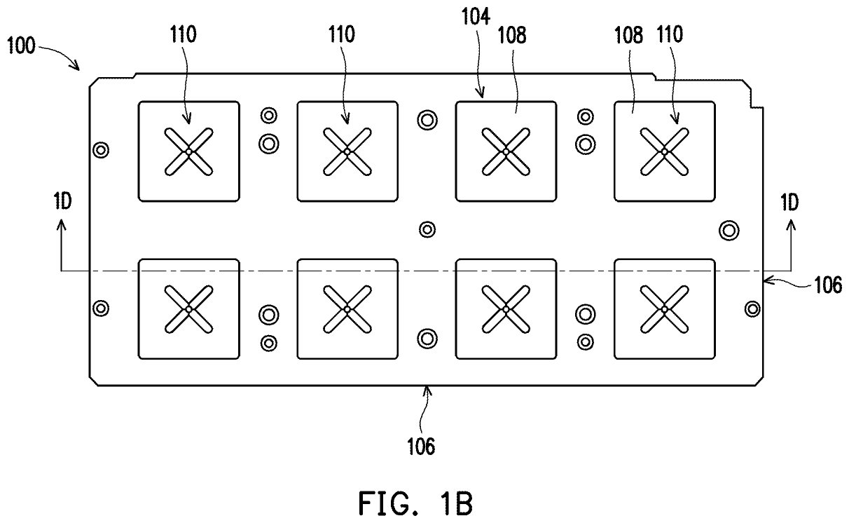

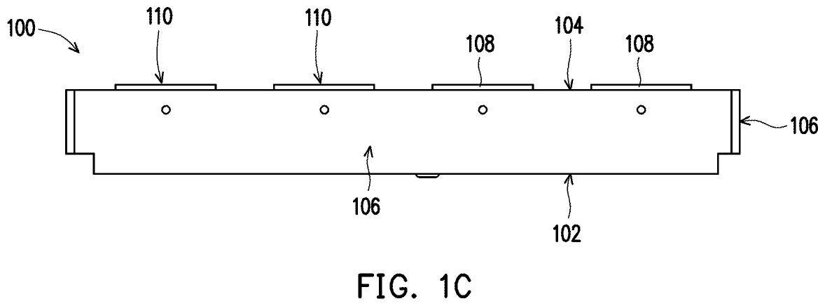

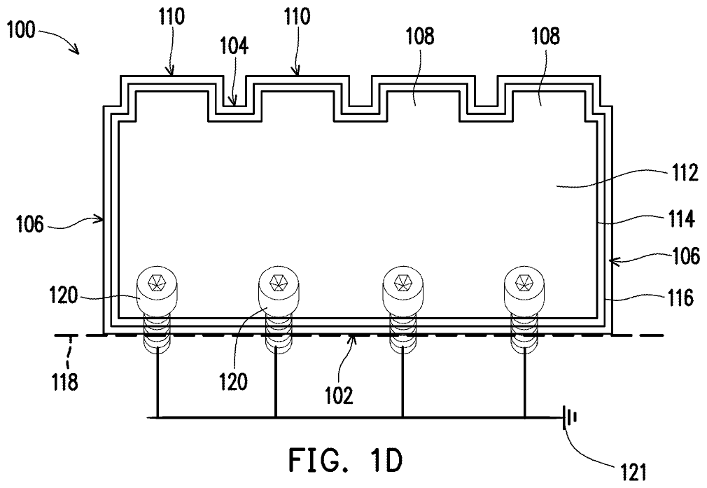

FIG. 1A is a perspective view of an example of an under boat support (UBS) 100, which includes a first surface 102 and a second surface 104 opposite to the first surface 102. FIG. 1B is a side view of the example of the UBS 100 as shown in FIG. 1A. FIG. 1C is a side view of the example of the UBS 100 as shown in FIG. 1C.

As shown in FIGS. 1A-1C, each one of a plurality of sidewalls 106 of the UBS 100 extends from the first surface 102 to the second surface 104, and each one of the plurality of sidewalls 106 is transverse to the first surface 102 and the second surface 104, respectively. The UBS 100 includes a plurality of protrusions 108 that protrude outward from the second surface 104 of the UBS 100. Each one of the plurality of protrusions 108 includes an end surface 110 at an end of each one of the plurality of protrusions 108, respectively. As shown in FIGS. 1A-1C, the plurality of protrusions 108 have a rectangular shape.

FIG. 1D is a cross-sectional view of the example of the UBS as shown in FIGS. 1A-1C taken along line 1D-1D as shown in FIG. 1B. As shown in FIG. 1D, the UBS 100 includes a conductive body 112, which may be made of a conductive material such as a metal material. For example, the metal material may be an aluminum material or some other suitable type of conductive or metal material. A first coating layer 114 is along the conductive body 112, and a second coating layer 116 is along the first coating layer 114 such that the first coating layer 114 is between the second coating layer 116 and the conductive body 112. The first coating layer 114 may be an anodized coating layer formed by anodizing the conductive body 112 to act as a barrier to prevent corrosion of the conductive body 112. The first coating layer 114 may be an oxide layer. The second coating layer 116 is an electrostatic discharge (ESD) safe ceramic layer that was deposited onto the first coating layer 114 such that electrostatic charges do not build up at or along respective surfaces of the UBS 100. The second coating layer 116 is configured to reduce or prevent occurrences of an electrostatic discharge when the UBS 100 was in use with a FAB to avoid exposing sensitive electrical components to electrostatic discharges. The second coating layer 116 is relatively thin and during use or manufacturing of semiconductor packages or devices within the FAB, the second coating layer 116 may partially deteriorate over time resulting in cracks in the second coating layer 116 resulting in respective surfaces of the conductive body 112 being electrically accessible through the second coating layer 116. This cracking or deterioration within the second coating layer 116 increases the likelihood of electrostatic discharging occurring that may cause damage to electrically sensitive components when manufacturing semiconductor packages within the FAB reducing a yield of usable and within tolerance packages that are manufactured utilizing the FAB. In other words, an increase in waste costs may result due to a greater number of defective or out of tolerance semiconductor packages being manufactured due to this increase in electrostatic discharges that occur, and an increase in repair and maintenance costs may result due to increased down times to conduct repairs or maintenance to reduce or prevent electrostatic discharges events within the FAB.

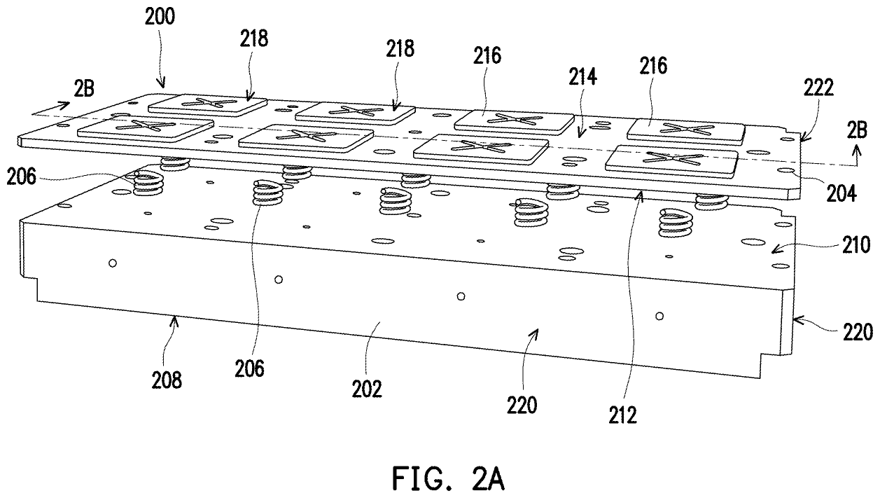

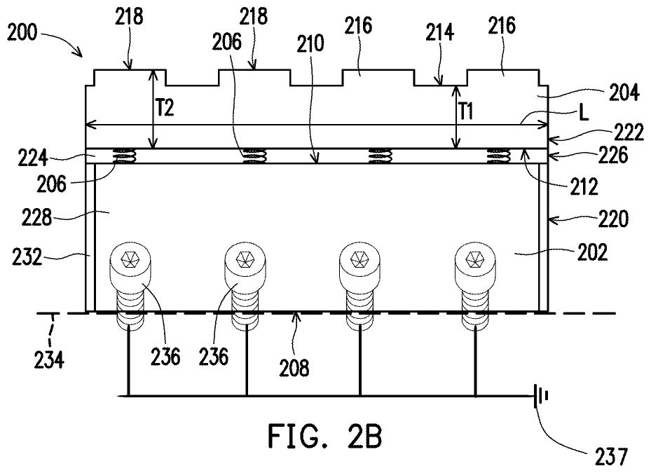

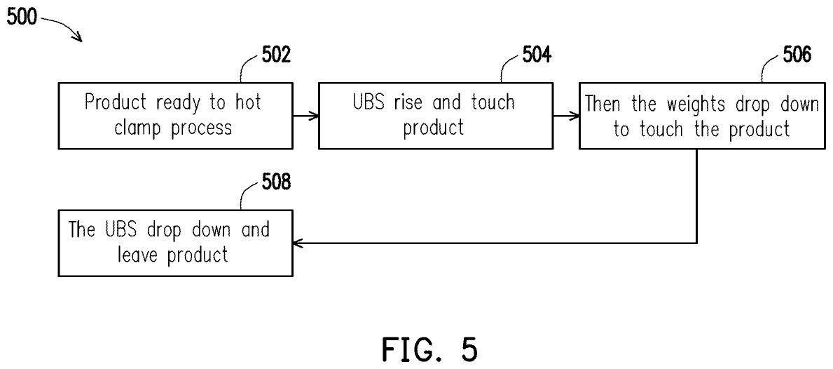

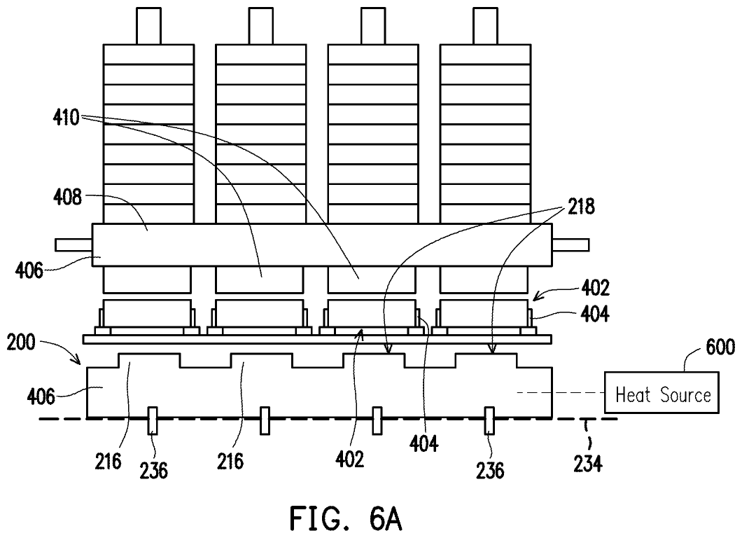

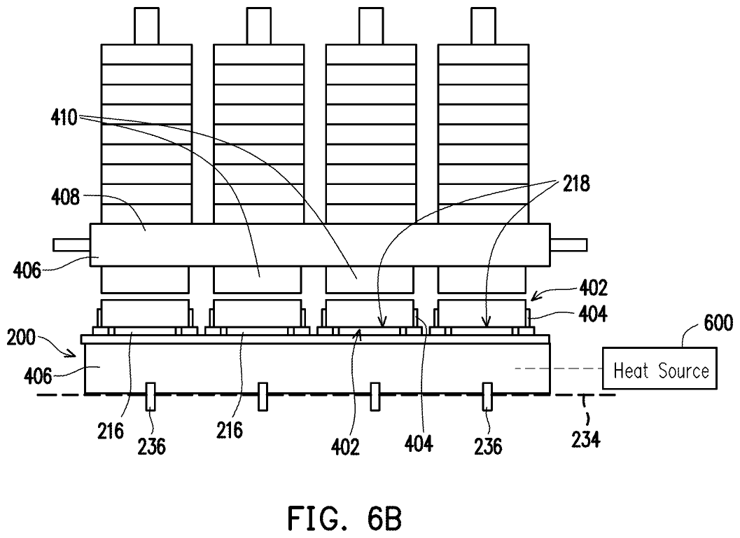

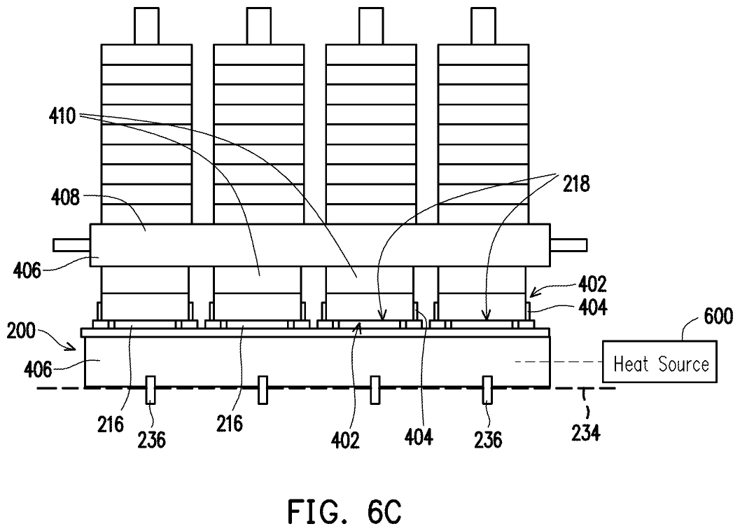

The partial deterioration or cracking of the second coating layer 116 may occur due to being utilized within a method of processing semiconductor packages or devices within the FAB. For example, the partial deterioration or cracking of the second coating layer 116 may occur when the UBS 100 is utilized in a method similar to the method discussed later herein with respect to FIGS. 5 and 6A-6C of the present disclosure. While the following discussion of FIGS. 5 and 6A-6C will be with respect to a UBS 200 as shown in FIGS. 2A-2C of the present disclosure, the example of the UBS 100 may be utilized in a similar method as discussed with respect to FIGS. 2A-2C. The utilization of the UBS 100 in the method similar to the method as shown and discussed with respect to FIGS. 5 and 6A-6C may result in the partial deterioration and cracking of the second coating layer 116 of the UBS 100. It will be readily appreciated based on the discussion within the present disclosure that the UBS 200 of the present disclosure as shown in FIGS. 2A-2C further reduces and further prevents occurrences of electrostatic discharges relative to the example of the UBS 100 as shown in FIGS. 1A-1D.

As shown in FIG. 1D, when in use the example of the UBS 100 may be mounted to a processing tool 118 by a plurality of fasteners 120. In some embodiments, the plurality of fasteners 120 may ground the conductive body 112 of the UBS 100 to the processing tool 118. For example, as shown in FIG. 1D, the plurality of fasteners 120 are coupled to a ground 121. The plurality of fasteners 120 may be screws, nuts and bolts, snap-fit fasteners, press-fit fasteners, or some other suitable type of fastener or combination of fasteners, respectively. The conductive body 112 may be grounded to the processing tool 118 to reduce or prevent electrostatic discharge events. However, when the second coating layer 116 is partially deteriorated or cracked as discussed above, the partial deterioration or cracking of the second coating layer 116 results in additional electrical pathways along which electrical charges or current may pass along such that a number of electrostatic discharge events that occur when utilizing the example of the UBS 100 increases resulting in a greater number of defective or out of tolerance semiconductor packages being manufactured by the FAB. Once the increase in defective or out of tolerance semiconductor packages is detected, a processing tool utilizing the example of the UBS 100 may be stopped to be repaired or maintained, and this downtime and repair time may result in increased costs in running the FAB. It will be readily appreciated, based on the discussion within the present disclosure, that the UBS 200 of the present disclosure as shown in FIGS. 2A-2C further reduces and further prevents occurrences of electrostatic discharges relative to the example of the UBS 100 as shown in FIGS. 1A-1D.

FIG. 2A is an exploded, perspective view of an under boat support (UBS) 200, in accordance with some embodiments. The UBS 200 includes a conductive body 202, an electrostatic discharge (ESD) safe ceramic body 204 that is on the conductive body 202, and a plurality of springs 206 that are between the conductive body 202 and the plurality of springs 206. The conductive body 202 includes a first surface 208 and a second surface 210 opposite to the first surface 208. The ESD safe ceramic body 204 includes a third surface 212 that faces the second surface 210 of the conductive body 202, and the ESD safe ceramic body 204 includes a fourth surface opposite to the third surface 212 and faces away from the conductive body 202. A plurality of protrusions 216 extend outward from the fourth surface of the ESD safe ceramic body 204 and extend away from the conductive body 202. Each one of the plurality of protrusions 216 includes an end surface 218 at an end of each one of the plurality of protrusions 216, respectively. Each one of the plurality of springs 206 includes a first end at the second surface 210 of the conductive body 202, and each one of the plurality of springs includes a second end opposite to a corresponding first end and at the third surface 212 of the ESD safe ceramic body 204. The plurality of springs 206 provides electrical pathways such that the ESD safe ceramic body is electrically coupled to the conductive body 202. In some embodiments, the first ends of the plurality of springs 206 may physically contact the second surface 210 of the conductive body 202, and the second ends of the plurality of springs 206 may physically contact the third surface 212 of the ESD safe ceramic body 204.

The conductive body 202 includes a plurality of first sidewalls 220 that extends from the first surface 208 to the second surface 210, and the plurality of first sidewalls 220 is transverse to the first surface 208 and the second surface 210, respectively. The ESD safe ceramic body 204 includes a plurality of second sidewalls 222 that extends from the third surface 212 to the fourth surface 214, respectively, and the plurality of second sidewalls 222 is transverse to the third surface 212 and the fourth surface 214, respectively. In some embodiments, ones of the plurality of first sidewalls 220 may be coplanar and flush with corresponding ones of the plurality of second sidewalls 222 when the conductive body 202 is coupled to the ESD safe ceramic body 204.

FIG. 2B is a cross-sectional view of the UBS 200 as shown in FIG. 2A, in accordance with some embodiments, taken along line 2B-2B as shown in FIG. 2A. As shown in FIG. 2B, the ESD safe ceramic body 204 is coupled to the conductive body 202 by an adhesive 224 that extends from the second surface 210 of the conductive body 202 to the third surface 212 of the ESD safe ceramic body 204. The adhesive 224 may be a high-temperature resistance adhesive or glue that is resistant to temperatures up to 250-degrees Celsius (° C.). For example, the adhesive 224 may remain in a substantially solid state until exposed to temperatures greater than 250-degrees Celsius (° C.), for example, up to 300-degrees Celsius (° C.). The adhesive 224 may include a plurality of third sidewalls 226 that are substantially coplanar and flush with corresponding ones of the plurality of first sidewalls 220 and the plurality of second sidewalls 222.

The conductive body 202 includes a conductive portion 228 and a coating layer 232 that covers sidewalls of the conductive portion 228. The coating layer 232 may be an anodized coating layer that is formed by anodizing the conductive portion 228 to act as a barrier to prevent corrosion of the conductive portion 228. The coating layer 232 may be an oxide layer.

As shown in FIG. 2B, in some embodiments of the UBS 200, the ESD safe ceramic body 204 may be completely or fully made of an ESD safe ceramic material to reduce or prevent occurrences of electrostatic discharge events when the UBS 200 is in use within the FAB. As shown in FIG. 2B, when in use the UBS 200 may be mounted to a processing tool 234 by a plurality of fasteners 236. In some embodiments, the plurality of fasteners 236 may ground the conductive body 202 of the UBS 200 to the processing tool 234. For example, as shown in FIG. 2B, the plurality of fasteners 236 are coupled to a ground 237. The plurality of fasteners 236 may be screws, nuts and bolts, snap-fit fasteners, press-fit fasteners, or some other suitable type of fastener or combination of fasteners, respectively. The conductive body 202 may be grounded to the processing tool 234 to reduce or prevent electrostatic discharge events. As the plurality of springs 206 provides electrical pathways between the ESD safe ceramic body 204 and the conductive body 202, the ESD safe ceramic body 204 is grounded as well through electrical pathways that allow for electrical charges to successively travel along the ESD safe ceramic body 204, the plurality of springs 206, the conductive body 202, and the plurality of fasteners 236 to the processing tool 234 such that the ESD safe ceramic body 204 is grounded through the processing tool 234. In other words, the UBS 200 is grounded to the processing tool 234 when the UBS 200 is mounted to the processing tool 234 with the plurality of fasteners 236.

The ESD safe ceramic body 204 includes a first thickness T1 that extends from the third surface 212 to the fourth surface 214 and a second thickness T2 that extends from the third surface 212 to ones of the plurality of end surfaces 218 of the plurality of protrusions 216. The first thickness T1 is less than the second thickness T2. In various embodiments, the second thickness T2 may be equal to a thickness in a range from 1-millimeter (mm) to 50-mm, or the second thickness T2 may be equal to the upper and lower ends of this range.

As shown in FIG. 2A, each one of the plurality of protrusions 216 has a rectangular shape. In some alternative embodiments of the UBS 200, the plurality of protrusions may have some shape different from the rectangular shape as shown in FIG. 2A, for example, the plurality of protrusions 216 may have a profile of a pentagon, an octagon, or some other profile with some other type of shape.

As shown in FIG. 2B, the ESD safe ceramic body 204 has a length L and has a width W (e.g., into and out of the page based on the orientation shown in FIG. 2B) that is orthogonal or perpendicular to the length L. In various embodiments, the length L may be equal to a length in a range of 250-mm to 350-mm, or the length L may be equal to the upper and lower ends of this range. In various embodiments, the width W may be equal to a width in a range of 100-mm to 200-mm, or the width W may be equal to the upper and lower ends of this range. The ESD safe ceramic body 204 may be heated within a range of 0-degrees Celsius (° C.) to 300-degrees Celsius (° C.), or may be heated up to the upper and lower ends of this range.

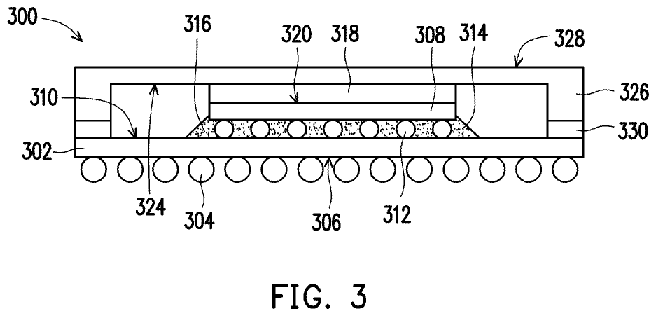

FIG. 3 is a cross-sectional view of a completed semiconductor package 300. The completed semiconductor package 300 may be formed utilizing a method of manufacturing of a flowchart 500 as shown in FIG. 5 of the present disclosure. The details of the method of manufacturing of the flowchart 500 as shown in FIG. 5 of the present disclosure will be discussed later herein.

The completed semiconductor package 300 includes a substrate 302 to which a plurality of solder balls 304 are coupled. The plurality of solder balls 304 are coupled to a first side 306 of the substrate 302. A semiconductor die 308 is coupled to a second side 310 of the substrate 302 that is opposite to the first side 306 of the substrate 302. A plurality of solder bumps 312 electrically couple the semiconductor die 308 to electrical structures (e.g., conductive vias, conductive traces, conductive layers, redistribution layers, etc.) within the substrate 302. The plurality of solder bumps 312 are within an underfill portion 314, which may be made of an underfill resin, epoxy, or polymer. The underfill portion 314 may include a fillet portion 316 that is at a peripheral of the semiconductor die 308. A thermal interface material (TIM) 318 extends from a surface 320 of the semiconductor die 308 to an inner surface 324 of a lid 326 of the completed semiconductor package 300, and the inner surface 324 of the lid 326 is opposite to an external surface of the lid 326. The TIM 318 provides a thermal pathway such that thermal energy or heat output by the semiconductor die 308 is dissipated through the TIM and the lid 326 of the completed semiconductor package 300. The lid 326 is coupled to the second side 310 of the substrate 302 by an adhesive 330.

As shown in FIG. 3, in some embodiments, the TIM 318 is uniformly distributed over the surface 320 of the semiconductor die 308, and the TIM 318 completely or fully covers the surface 320 of the semiconductor die 308. The TIM 318 is uniformly distributed over the surface 320 such that the TIM 318 has a thickness T3 that remains substantially the same along an entirety of the TIM 318.

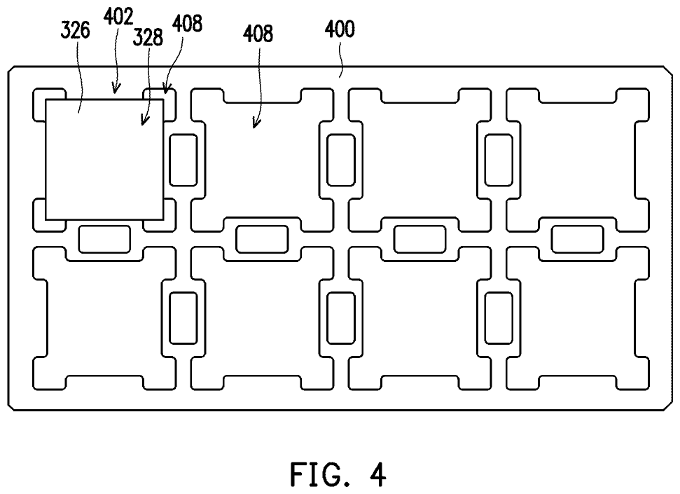

FIG. 4 is a top plan view of an example of a carrier 400 on which a partially processed semiconductor package 402 is present. In some instances, the partially process semiconductor package 402 may be referred to as a partially processed die assembly. The partially processed semiconductor package 402 may be a partially processed version of the completed semiconductor package 300 as shown in FIG. 3 of the present disclosure. For example, the partially processed semiconductor package 402 may include the substrate 302, the semiconductor die 308, the plurality of solder bumps 312, the underfill portion 314, the TIM 318, the lid 326, and the adhesive 330. However, the TIM 318 may not yet be uniformly distributed over the surface 320 of the semiconductor die 308. For example, while the TIM 318 may be on a central area of the surface 320 of the semiconductor die 308, the TIM 318 may not yet be present on a peripheral area of the surface 320 of the semiconductor die such that the TIM 318 does not yet completely or fully cover the surface 320 of the semiconductor die 308. Although the TIM 318 is not yet uniformly distributed over the surface 320 of the semiconductor die 308, the TIM 318 may be uniformly distributed over the surface 320 of the semiconductor die 308 by carrying out the method of manufacturing of the flowchart 500 as shown in FIG. 5, which will be discussed later herein.

The partially processed semiconductor package 402 may be temporarily mounted to the carrier 400 utilizing a temporary adhesive 404, which may be more readily seen in FIGS. 6A-6C of the present disclosure. The partially processed semiconductor package 402 is temporarily mounted to the carrier 400 to overlap one of a plurality of openings 408 that extend through the carrier 400. While only the one partially processed semiconductor package 402 is shown being mounted to the carrier 400 in FIG. 4, a plurality of the partially processed semiconductor packages 402 may be temporarily mounted to the carrier 400 and each one of the plurality of partially processed semiconductor packages 402 overlaps a corresponding one of the plurality of openings 408. For example, as there are eight of the plurality of openings 408, there may be eight of the partially processed semiconductor packages 402 temporarily mounted to the carrier 400.

FIG. 5 is the flowchart 500 of the method of manufacturing the completed semiconductor package 300 to uniformly distribute the TIM 318 on the surface 320 of the semiconductor die 308.

In a first step 502, a plurality of partially processed semiconductor packages 402 are temporarily mounted to the carrier 400 by the temporary adhesive 404. The semiconductor packages 402 being temporarily mounted to the carrier 400 by the temporary adhesive 404 may be readily seen in FIGS. 6A-6C of the present disclosure. For example, in some embodiments, the temporary adhesive 404 may be deposited onto the carrier 400, and, after the temporary adhesive 404 is deposited on the temporary adhesive 404, a pick-and-place machine may place the plurality of partially processed semiconductor packages 402 onto the temporary adhesive 404 to temporarily mount the plurality of partially processed semiconductor packages 402 to the carrier 400. After each one of the plurality of partially processed semiconductor packages 402 is temporarily mounted to the carrier 400 by the temporary adhesive 404, the carrier 400 on which the plurality of partially processed semiconductor packages 402 is placed between a clamp structure 406 of the processing tool 234. The clamp structure 406 includes the UBS 200, which is mounted to the processing tool 234 by the plurality of fasteners 236, and a weighted portion 409 that includes a plurality of clamp or press protrusions or portions 410. Each one of the plurality of clamp portions 410 overlaps and is aligned with a corresponding one of the plurality of protrusions 216 of the UBS 200. The plurality of clamp portions 410 may be made of a thermosetting plastic material such as, for example, a polyoxybenzylmethylenglycolanhydride material, which is a thermosetting phenol formaldehyde resin formed from a condensation reaction of phenol with formaldehyde. For example, the plurality of clamp portions may be made of a plastic identified by the trademark Bakelite™. This thermosetting plastic may be a high temperature resistant thermosetting plastic and the thermosetting plastic may be electrically insulative. The carrier 400 on which the plurality of partially processed semiconductor packages 402 are present may readily be shown being positioned within a clamp structure 406 of the processing tool 234 in FIG. 6A.

After the first step 502, in a second step the UBS 200 rises up such that each one of the plurality of end surfaces 218 of the plurality of protrusions comes into contact with a corresponding one of the plurality of partially processed semiconductor packages 402. For example, each one of the plurality of end surfaces 218 may come into contact with the first side 306 of the substrate 302. When UBS 200 rises up, each one of the plurality of protrusions 216 passes through a corresponding one of the plurality of openings 408 such that each one of the plurality of end surfaces 218 comes into contact with the corresponding one of the plurality of partially processed semiconductor packages 402. The UBS 200 rising up to contact the plurality of partially processed semiconductor packages 402 may be readily seen in FIG. 6B.

After the second step 504, in a third step 506 the weighted portion 409 is dropped downward such that each one of the plurality of clamp portions 410 comes into contact with a corresponding one of the plurality of partially processed semiconductor packages 402 such that each one of the plurality of partially processed semiconductor packages 402 is sandwiched between the UBS 200 and the weighted portion 409, respectively. For example, each one of the plurality of clamp portions 410 may contact the external surface 328 of the lid 326 of a corresponding one of the plurality of partially processed semiconductor packages 402. Either before the weighted portion 409 is dropped down onto the plurality of partially processed semiconductor packages 402, while the weighted portion 409 is being dropped downward onto the plurality of partially processed semiconductor packages 402, after the clamp portions 410 come into contact with the partially processed semiconductor packages 402, or during all of the above, the UBS 200 is heated by a heat source 600 that is thermally coupled to the UBS 200. The UBS 200 being heated by the heat source 600 while the plurality of protrusions 216 of the UBS 200 and the clamp portions 410 of the weighted portion 409 clamp down onto the plurality of partially processed semiconductor packages 402 results in the TIM 318 of the plurality of partially processed semiconductor packages 402 being pressed downward as well between corresponding ones of the lids 326 and corresponding ones of the semiconductor dice 308 of the plurality of partially processed semiconductor packages 402. The TIM 318 being exposed to this clamping pressure and heat results in the TIM 318, which was not previously uniformly distributed across the surfaces 320 of the semiconductor die of the plurality of partially processed semiconductor packages 402, being squeezed and deformed such that the TIM 318 of the plurality of partially processed semiconductor packages 402 is uniformly distributed on the surfaces 320. For example, the TIM 318 after this third step is carried out, which may readily be seen in FIG. 6C, the TIM 318 of the plurality of partially processed semiconductor packages 402 may look similar or the same as the TIM 318 of the completed semiconductor package 300 as shown in FIG. 3 of the present disclosure. For example, the TIM 318 of each one of the plurality of partially processed semiconductor packages 402 is now uniformly distributed across the surfaces 320 such that the TIM 318 has a thickness that is substantially the same across the surfaces 320 and completely or fully covers the surfaces 320 in the same or similar manner as shown in the completed semiconductor package 300 as shown in FIG. 3.

If the example of the UBS 100 is utilized to carry out the above method of manufacturing of the flowchart 500, there is a higher likelihood of electrostatic discharge (ESD) that would occur during the third step. For example, when the UBS 100 is utilized and the UBS 100 includes cracks, deterioration, or defects in the second coating layer 116, which again is an ESD safe ceramic layer, the likelihood of electrostatic discharging occurring is higher and is not prevented resulting in sensitive electrical components within the plurality of partially processed semiconductor packages 402 being exposed to electrostatic discharge (ESD) that damages the sensitive electrical components resulting in the manufacture of defective or out of tolerance semiconductor packages, which increases waste costs and other costs such as maintenance and repair costs. In other words, utilizing the UBS 200 as shown in FIGS. 2A and 2B over the example of the UBS 100 as shown in FIGS. 1A-1D reduces or prevents electrostatic discharge (ESD) events increasing the yield of completed semiconductor packages within tolerance. For example, when the UBS 100 is utilized and there are one or more cracks or defects in the second coating layer 116, an electrostatic discharge (ESD) event generally occurs either between the second step 504 as the weighted portion 409 moves closer to the UBS 100 and the third step 506, or during the third step 506 as the plurality of partially processed semiconductor packages 402 are being clamped down on and are being heated by heating the UBS 100 utilizing the heat source 600. If the electrostatic discharge (ESD) event occurs either between the second step 504 and the third step 506 or during the third step 506, the electrostatic charge or current will likely pass through electrically sensitive components of the plurality of partially processed semiconductor packages 402 damaging the electrically sensitive components resulting in the manufacture of one or more defective completed semiconductor packages that may not be shipped and sold to customers and instead become waste increasing costs that are absorbed by a manufacturer of semiconductor packages. On the other hand, if the UBS 200 was utilized with the ESD safe ceramic body 204 that is fully or completely made of an ESD safe ceramic material, the ESD safe ceramic body 204 being thicker than the second coating layer 116 of the UBS 100 further reduces and prevents these electrostatic discharge (ESD) events from occurring altogether. For example, the ESD safe ceramic body 204 being thicker than the second coating layer 116 further reduces or prevents these electrostatic discharge (ESD) events from occurring even when there were minor cracks or defects within the ESD safe ceramic body 204, whereas these types of cracks or defects within the second coating layer 116 may result in an increase in the likelihood of electrostatic discharge (ESD) events occurring more frequently resulting in a yield of semiconductor packages that are manufactured within tolerance. In other words, the UBS 200 with the ESD safe ceramic body 204 reduces or prevents electrostatic discharge (ESD) events from occurring as compared to the UBS 100 with the second coating layer 116 of the ESD safe ceramic material as the ESD safe ceramic body 204 is thicker than the second coating layer 116.

After the third step 506, in a fourth step 508 the weighted portion 409 rises up such that the clamp portions 410 no longer contact the plurality of partially processed semiconductor packages 402 and the UBS 200 is dropped downward such that the end surfaces 218 of the plurality of protrusions 216 no longer contacts the plurality of partially processed semiconductor packages 402. The carrier 400 on which the plurality of partially processed semiconductor packages 402 may be removed from between the UBS 200 and the weighted portion 409 of the clamp structure 406 of the processing tool 234. The plurality of partially processed semiconductor packages 402 in which the TIM 318 is now uniformly distributed due to carrying out the method of manufacturing in the flowchart 500 may be removed from the carrier 400. The plurality of partially processed semiconductor packages 402 may be further processed by forming the plurality of solder balls 304 a plurality of completed semiconductor packages 300, which are the same or similar to the completed semiconductor package 300 as shown in FIG. 3. Alternatively, after the method of manufacturing in the flowchart 500 is carried out and the plurality of partially processed semiconductor packages 402 are removed from the carrier 400, the plurality of partially processed semiconductor packages 402 may be completed semiconductor packages that are the same or similar to the completed semiconductor package 300 as shown in FIG. 3 but that do not include the plurality of solder balls 304. Alternatively, after the fourth step 508, other further types of processing steps may be carried out on the plurality of partially processed semiconductor packages 402 such that the plurality of partially processed semiconductor packages 402 with the uniformly distributed TIM 318 becomes completed or finished semiconductor packages, for example, the example of the completed semiconductor package 300 as shown in FIG. 3.

Although the first, second, third, and fourth steps 502, 504, 506, 508, respectively, are discussed in the order as set for in the flowchart 500, in alternative embodiments, the first, second, third, and fourth steps 502, 504, 506, 508 may be reorganized for processing and manufacturing completed semiconductor packages. For example, these completed semiconductor packages may be the same, similar to, or different from the completed semiconductor package 300 as shown in FIG. 3.

While not shown in FIGS. 6A-6C, in some embodiments, the plurality of fasteners 236 are grounded by the ground 237 (see FIG. 2B of the present disclosure). In other words, the plurality of fasteners 236 may ground the conductive body 202 of the UBS 200.

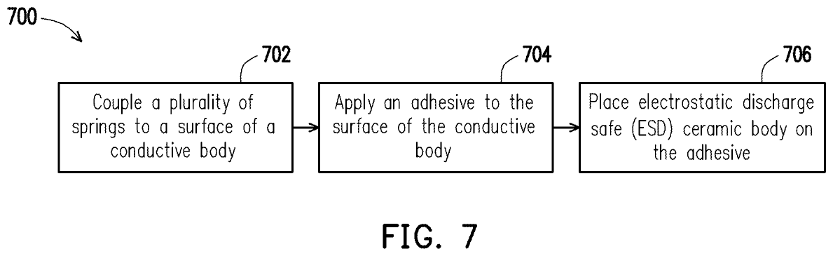

FIG. 7 is a flowchart 700 of a method of manufacturing the UBS 200 as shown in FIGS. 2A and 2B, in accordance with some embodiments. In a first step 702, the plurality of springs 206 are mounted to the second surface 210 of the conductive body 202. For example, the conductive body 202 may include one or more reception structures or openings that receive the first ends of each one of the plurality of springs 206 such that the springs 206 are mounted to the conductive body 202 and are present at the second surface 210 of the UBS 200. After the first step 702, in a second step 704 the adhesive 224 may be deposited or formed on the second surface 210 of the conductive body 202 to partially encase the plurality of springs 206 at the second surface 210 of the conductive body 202. After the second step 704, in a third step 706 the ESD safe ceramic body 204 is placed onto the adhesive 224 such that the adhesive 224 adheres or couples the ESD safe ceramic body 204 to the second surface 210 of the conductive body 202. When the ESD safe ceramic body 204 is adhered or coupled to the second surface 210 of the conductive body 202, the third surface 212 of the ESD safe ceramic body 204 may come into contact with the second ends of each one of the plurality of springs 206 or may come into close proximity with the second ends of each one of the plurality of springs 206 such that electrical pathways are present between the second surface 210 and the third surface 212 through the plurality of springs 206. In other words, the ESD safe ceramic body 204 is electrically coupled to the conductive body 202 through the plurality of springs 206.

Although the first, second, and third steps 702, 704, 706, respectively, are discussed in the order as set for in the flowchart 700, in alternative embodiments, the first, second, and third steps 702, 704, 706 may be reorganized to manufacture a UBS that may be utilized within a processing tool with the FAB. For example, this UBS may be the same, similar to, or different from the UBS 200 as shown in FIGS. 2A and 2B of the present disclosure.

In view of the discussion within the present disclosure, the UBS 200 further reduces or prevents electrostatic discharge (ESD) events when manufacturing or processing partially processed semiconductor packages to form completed semiconductor packages as compared to the UBS 100. In other words, the UBS 200 is more readily effective in reducing, and in some cases, preventing electrostatic discharge (ESD) events as compared to the UBS 100. This is because the ESD safe ceramic body 204 is completely and fully made of an ESD safe ceramic material and is thicker than the second coating layer 116 of the UBS 100. The greater thickness of the ESD safe ceramic body 204 of the UBS 200 reduces the likelihood of the conductive body 202 being exposed further reducing or preventing electrostatic discharge (ESD) events. For example, small cracks or minor defects in the ESD safe ceramic body 204 of the UBS 200 likely not result in occurrences of electrostatic discharge (ESD), whereas the same or similar small cracks or minor defects in the second coating layer 116 of the UBS 100 likely would result in occurrences of electrostatic discharge (ESD) events that may result in damaging electrically sensitive components when manufacturing completed semiconductor packages within the FAB. Utilizing the UBS 200 over the UBS 100 may increase a yield of completed semiconductor packages within selected tolerance and may decrease waste costs as fewer defective semiconductor packages are manufactured out of tolerance.

An under boat support (UBS) may be summarized as including: a conductive body including a surface; a high temperature resistant glue on the surface of the conductive body; an electrostatic discharge (ESD) safe ceramic body coupled to the surface of the conductive body by the high temperature resistant glue; and at least one spring present within the high temperature resistant glue and extending through the high temperature resistant glue from the conductive body to the ESD safe ceramic body, the at least one spring includes a first end at the surface of the conductive body and a second end opposite to the first end at the ESD safe ceramic body.

A method may be summarized as including: coupling a die assembly to a carrier overlapping an opening in the carrier; positioning the carrier on which the die assembly is present within a clamp structure; contacting a first surface of the die assembly with a protrusion of an electrostatic discharge (ESD) safe ceramic body of an under boat support the clamp structure; and uniformly distributing a thermal interface material on a die of the die assembly by clamping the die assembly with the clamp structure and by heating the under boat support of the clamp structure.

A method may be summarized as including: disposing at least one conductive spring on a surface of a conductive body; forming a high-temperature resistant adhesive on the surface of the conductive body; and coupling an electrostatic discharge (ESD) safe ceramic body to a conductive body with the high-temperature resistant adhesive.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An under boat support, comprising:
a conductive body including a surface;
a high temperature resistant glue on the surface of the conductive body;
an electrostatic discharge (ESD) safe ceramic body coupled to the surface of the conductive body by the high temperature resistant glue; and
at least one spring present within the high temperature resistant glue and extending through the high temperature resistant glue from the conductive body to the ESD safe ceramic body, the at least one spring includes a first end at the surface of the conductive body and a second end opposite to the first end at the ESD safe ceramic body.

2. The under boat support of claim 1, wherein the ESD safe ceramic body includes a plurality of protrusions and a plurality of recesses between ones of the plurality of protrusions.

3. The under boat support of claim 2, wherein each one of the plurality of protrusions is rectangular.

4. The under boat support of claim 1, wherein:
the conductive body includes a plurality of sidewalls that are transverse to the surface of the conductive body; and
each one of the plurality of sidewalls is covered by a coating layer.

5. The under boat support of claim 4, wherein the coating layer is an oxide coating layer.

6. The under boat support of claim 4, wherein the coating layer is configured to prevent corrosion of the conductive body.

7. The under boat support of claim 1, wherein the conductive body includes a mounting surface opposite to the surface of the conductive body, and the mounting surface includes one or more fastening structures structured to receive one or more fasteners.

8. The under boat support of claim 1, wherein the high temperature resistant glue is resistant to temperatures up to 250-degrees Celsius (° C.).

9. The under boat support of claim 1, wherein the first end of the spring contacts the surface of the conductive body and the second end contacts the ESD safe ceramic body.

10. The under boat support of claim 1, wherein:
the conductive body further includes:
a mounting surface opposite to the surface of the conductive body; and
a first thickness that extends from the surface of the conductive body to the mounting surface of the conductive body;
the ESD safe ceramic body further includes:
a support surface;
a surface opposite to the support surface;
a plurality of protrusions protruding outward from the support surface, each one of the plurality of protrusions including an end surface;
a plurality of recesses at the support surface and between ones of the plurality of protrusions; and
a second thickness that extends from the surface of the ESD safe ceramic body to the end surfaces of the plurality of protrusions, the second thickness is less than the first thickness of the conductive body.

11. The under boat support of claim 10, wherein the high temperature resistant glue couples the surface of the conductive body to the surface of the ESD safe ceramic body.

12. The under boat support of claim 1, wherein the spring is conductive.

13. A method, comprising:
coupling a die assembly to a carrier overlapping an opening in the carrier;
positioning the carrier on which the die assembly is present within a clamp structure;
contacting a first surface of the die assembly with a protrusion of an electrostatic discharge (ESD) safe ceramic body of an under boat support of the clamp structure; and
uniformly distributing a thermal interface material on a die of the die assembly by clamping the die assembly with the clamp structure and by heating the under boat support of the clamp structure.

14. The method of claim 13, wherein uniformly distributing a thermal interface material of the die assembly on the die of the die assembly by contacting the die assembly with a weighted portion of the clamp structure.

15. The method of claim 14, wherein contacting the die assembly with the weighted portion of the clamp structure further includes applying a pressure to a lid of the die assembly to uniformly distribute the thermal interface material, which is between the lid and the die, of the die assembly on the die of the die assembly.

16. The method of claim 15, further comprising, after uniformly distributing the thermal interface material on the die, moving the ESD safe ceramic body and the weighted portion away from the die assembly and the carrier.

17. The method of claim 16, further comprising, after moving the ESD safe ceramic body and the weighted portion to a non-clamp position, removing the carrier from the clamp structure on which the die assembly is present.

18. A method, comprising:
disposing at least one conductive spring on a surface of a conductive body;
forming a high-temperature resistant adhesive on the surface of the conductive body; and
coupling an electrostatic discharge (ESD) safe ceramic body to a conductive body with the high-temperature resistant adhesive.

19. The method of claim 18, further comprising forming a coating layer on a plurality of sidewalls of the conductive body.

20. The method of claim 19, wherein forming the coating layer on the plurality of sidewalls of the conductive body includes an electrochemical process.
